(19) United States
(12) Patent Application Publication
(10) Pub. No.: US 2019/0148412 A1
(43) Pub. Date: May 16, 2019

(54) MULTILAYER WIRING FILM AND THIN FILM TRANSISTOR ELEMENT

(71) Applicant: Kabushiki Kaisha Kobe Seiko Sho (Kobe Steel, Ltd.), Hyogo (JP)

(72) Inventors: Yoko SHIDA, Kobe-shi, Hyogo (JP); Hiroshi GOTO, Kobe-shi, Hyogo (JP)

(73) Assignee: Kabushiki Kaisha Kobe Seiko Sho (Kobe Steel, Ltd.), Hyogo (JP)

(21) Appl. No.: 16/092,976

(22) PCT Filed: May 10, 2017
(86) PCT No.: PCT/JP2017/017690

§ 371 Date: Oct. 11, 2018

(30) Foreign Application Priority Data
May 13, 2016 (JP) 2016-097321

(51) Int. Cl. H01L 27/12; C22C 9/04; C22C 9/01; C22C 9/05; C22C 9/06; C03C 17/09; C23C 16/02; C23C 16/34; H01L 29/49; H01L 29/786

(52) U.S. Cl. CPC H01L 27/1244; C23C 16/401; C22C 9/01; C22C 9/05; C22C 9/06; C03C 17/09; C23C 16/0281; C23C 16/34; H01L 27/1225; H01L 29/4908; H01L 29/7869; H01L 29/78678; C03C 2217/253; C03C 2218/156; C03C 2218/31; C22C 9/04

(57) ABSTRACT

The multilayer wiring film which is provided with a wiring layer that is formed of Cu or a Cu alloy and has an electrical resistance of 10 μΩcm or less and a Cu—X alloy layer that contains Cu and an element X and is arranged above and/or below the wiring layer, and wherein the element X is composed of at least one element selected from the group X consisting of Al, Mn, Zn and Ni, and the metals constituting the Cu—X alloy layer have a specific composition. The multilayer wiring film is able to provide a multilayer wiring film which has low electrical resistance and is free from film separation during the formation of a SiOx film by a CVD method, said SiOx film serving as an interlayer insulating film, and which is also free from an increase in the electrical resistance even if subjected to a high-temperature heat treatment that is carried out at 400° C. or higher.

### TECHNICAL FIELD

The present invention relates to a multilayer wiring film and a thin film transistor element.

### BACKGROUND ART

Oxide semiconductors and low temperature poly-silicon (hereafter also referred to as LTPS) semiconductors have been known as semiconductor materials for thin film transistors (hereafter also referred to as TFTs) used for display devices such as flat panel displays and touch panels, e.g., liquid crystal panels and organic EL (electroluminescence) panels.

Oxide semiconductors and LTPS semiconductors have higher electron mobility than known amorphous silicon semiconductor materials and thus can achieve high-speed driving of TFT elements.

Switching speed of TFT elements has been increased by decreasing the resistance of wiring materials. Although an Al (aluminum) thin film or an ITO (indium tin oxide) thin film has been used for electrode wiring for known flat panel displays, use of Cu (copper) electrode wiring or Cu alloy electrode wiring having a lower electrical resistance has been proposed.

However, the following problems are posed when such Cu wiring is used. For example, TFT elements including an oxide semiconductor or an LTPS semiconductor need to be subjected to a higher temperature heat treatment process than known elements including amorphous silicon and thus need to endure heating at about 400° C. to 500° C. In addition, the Cu wiring has poor adhesion to glass substrates, semiconductor films such as Si (silicon) films, and metal oxide films.

For the technique that uses Cu, PTL 1 discloses a display device including a Cu alloy film having good adhesion to transparent substrates such as glass substrates. In the display device disclosed in PTL 1, the Cu alloy film has a multilayer structure that includes a first layer (Y) formed of a Cu alloy containing at least one element selected from the group consisting of Zn, Ni, Ti, Al, Mg, Ca, W, Nb, and Mn in an amount of 2 to 20 at % in total and a second layer (X) formed of pure Cu or a Cu alloy that contains Cu as a main component and has a lower electrical resistivity than the Cu alloy of the first layer (Y), wherein the first layer (Y) is in contact with a transparent substrate. In this structure, good adhesion of the Cu alloy film to the transparent substrate and low electrical resistance are achieved.

PTL 2 discloses a Cu alloy wiring film for touch panel sensors, the Cu alloy wiring film having high oxidation resistance and being connected to a transparent conductive film. The wiring film has a multilayer structure that includes a Cu alloy (first layer) containing at least one alloy element selected from the group consisting of Ni, Zn, and Mn in an amount of 0.1 to 40 at % in total and a second layer formed of pure Cu or a Cu alloy that contains Cu as a main component and has a lower electrical resistivity than the Cu alloy of the first layer. The second layer is connected to the transparent conductive film.

In the process of forming a TFT element, a SiOx film serving as an interlayer insulating film is formed by a CVD (chemical vapor deposition) method. A SiOx film with less impurities can be formed by performing film formation at high temperature. Since impurities adversely affect the driving of TFT elements, the Cu wiring needs to endure the film formation of the SiOx film by a CVD method at a high temperature of 300° C. or higher. However, Cu has a high affinity for oxygen. When the SiOx film is formed by a CVD method, a N₂O gas is introduced. The N₂O gas is present in the form of oxygen radicals in the plasma. When a SiOx film is formed on a Cu single film at a high temperature of 300° C. or higher, the oxygen radicals and Cu readily react with each other as illustrated in FIG. 3 and FIG. 4, which causes formation of copper oxide and film separation. As illustrated in FIG. 3(a) and FIGS. 4(a) and 4(b), when a SiOx film is formed by a CVD method at a temperature of about 200° C., film separation is not observed. However, as illustrated in FIG. 3(b), when a SiOx film is formed at a temperature of about 300° C., film separation occurs.

### CITATION LIST

### Patent Literature

PTL 1: Japanese Unexamined Patent Application Publication No. 2011-48323

PTL 2: Japanese Unexamined Patent Application Publication No. 2013-120411

### SUMMARY OF INVENTION

### Technical Problem

As described above, a SiOx film serving as a gate insulating film (interlayer insulating film) is formed by a CVD method at 300° C. or higher in TFT elements including an oxide semiconductor or an LTPS semiconductor. Therefore, a cap layer needs to be laminated on the Cu wiring to reduce the damage to the Cu wiring during formation of the SiOx film. It is generally known that a Cu-30 at % Ni alloy film is used as a cap layer. By laminating the Cu-30 at % Ni alloy film, film separation can be suppressed as illustrated in FIG. 5 even when a SiOx film is formed by a CVD method at 300° C. or higher. However, if heat treatment at 400° C. or higher is performed, the resistance of the laminated film increases.

Flat panel displays including TFT elements including an oxide semiconductor or an LTPS semiconductor are promising for use as high-definition panels. In high-definition panels, to increase the aperture ratio, source/drain lines and gate lines are processed so as to have a wiring width of 10 μm or less. For the wiring shape, the case where a cap layer 13 extends farther than a wiring layer 12 and thus an extended portion 13a is formed as illustrated in FIG. 6(a) and the case where a reverse tapered shape is formed as illustrated in FIG. 6(b) cause breakage of an interlayer insulating film and wiring laminated above these layers. Therefore, the wiring shape needs to be controlled so as to be a forward tapered shape (refer to FIG. 6(c)). In the case where the wiring shape is a forward tapered shape, if the taper angle of the wiring layer 12 relative to a substrate 11 is small, the width of a Cu wiring portion exposed at the end of the wiring layer 12 increases. Therefore, the taper angle also needs to be controlled.

In PTL 1, for example, Ni, which is an element that increases the resistance through heat treatment at 400° C. or higher, is added to the cap layer. Furthermore, for example, Zn, which is an element that decreases the taper angle, is contained. Thus, the width of a Cu wiring portion exposed sometimes increases. In PTL 2, the application is limited to touch panels, the connection with an ITO thin film is required, and Ni, which is an element that increases the resistance through heating at 500° C., is contained.

Accordingly, it is an object of the present invention to provide a multilayer wiring film which has a low electrical resistance, in which film separation does not occur during formation of a SiOx film serving as an interlayer insulating film by a CVD method, and whose electrical resistance does not increase even when high-temperature heat treatment at 400° C. or higher is performed. It is also an object of the present invention to provide a thin film TFT element including the multilayer wiring film.

### Solution to Problem

As a result of thorough studies, the present inventors have found that the above objects can be achieved by using a Cu multilayer wiring film including a cap layer formed of a particular alloy layer, and have completed the present invention.

That is, the present invention relates to [1] to [7] below.

[1] A multilayer wiring film includes a wiring layer that has an electrical resistance of 10 μΩcm or less and is formed of Cu or a Cu alloy and a Cu—X alloy layer that is disposed above and/or below the wiring layer and contains Cu and an element X, wherein the element X is at least one element selected from the group X consisting of Al, Mn, Zn, and Ni, metals constituting the Cu—X alloy layer have a composition represented by any one of (1) to (5) below, and a wiring pattern has a width of 10 μm or less:

(1) only one element of the group X is contained in an amount of 6 at % or more and 27 at % or less,

(2) Al is contained in an amount of 4 at % or more and 15 at % or less and Mn is further contained in an amount of 5 at % or more and 10 at % or less,

(3) Zn is contained in an amount of 5 at % or more and 10 at % or less and Mn is further contained in an amount of 5 at % or more and 26 at % or less,

(4) Zn is contained in an amount of 4 at % or more and 14 at % or less and Al is further contained in an amount of 5 at % or more and 15 at % or less, and

(5) Al is contained in an amount of 5 at % or more and 10 at % or less and Ni is further contained in an amount of 2 at % or more and 10 at % or less.

[2] In the multilayer wiring film according to [1], metals constituting the Cu—X alloy layer have a composition represented by any one of (1′) to (5′) below, and a wiring pattern has a width of 5 μm or less:

(1′) only one element of the group X is contained in an amount of 6 at % or more and 14 at % or less,

(2′) Al is contained in an amount of 4 at % or more and 9 at % or less and Mn is further contained in an amount of 5 at % or more and 10 at % or less,

(3′) Zn is contained in an amount of 5 at % or more and 10 at % or less and Mn is further contained in an amount of 5 at % or more and 10 at % or less,

(4′) Zn is contained in an amount of 4 at % or more and 14 at % or less and Al is further contained in an amount of 5 at % or more and 10 at % or less, and

(5′) Al is contained in an amount of 5 at % or more and 10 at % or less and Ni is further contained in an amount of 6 at % or more and 10 at % or less.

[3] In the multilayer wiring film according to [1] or [2], the multilayer wiring film is laminated on a substrate, and the multilayer wiring film further includes an adhesive layer containing Ti on a surface that is closer to the substrate.
[4] In the multilayer wiring film according to [1] or [2], the wiring layer has a thickness of 50 nm or more and 1000 nm or less, and the Cu—X alloy layer has a thickness of 5 nm or more and 200 nm or less.
[5] In the multilayer wiring film according to [3], the wiring layer has a thickness of 50 nm or more and 1000 nm or less, and the Cu—X alloy layer has a thickness of 5 nm or more and 200 nm or less.
[6] A thin film transistor element includes the multilayer wiring film according to [1] and an oxide semiconductor.
[7] A thin film transistor element includes the multilayer wiring film according to [2] and a low temperature poly-silicon semiconductor or an oxide semiconductor.

### Advantageous Effects of Invention

The present invention can provide a multilayer wiring film for Cu wiring and a TFT element. In the multilayer wiring film, a low electrical resistance is achieved, film separation does not occur during formation of a SiOx film serving as an interlayer insulating film by a CVD method, and the electrical resistance does not increase even when high-temperature heat treatment at 400° C. or higher is performed. In particular, the multilayer wiring film having the structure of [1] can be suitably used for TFT elements including an oxide semiconductor. The multilayer wiring film having the structure of [2] can be suitably used for TFT elements including a low temperature poly-silicon semiconductor or an oxide semiconductor.

### BRIEF DESCRIPTION OF DRAWINGS

FIG. 1 is a schematic sectional view illustrating a structure of a multilayer wiring film according to the present invention.

FIG. 2 is a schematic sectional view illustrating a structure of a thin film transistor element including the multilayer wiring film according to the present invention.

FIG. 3 includes photographs each illustrating an external appearance obtained when a SiOx film is formed on a Cu single film by a CVD method. FIG. 3(a) is a photograph illustrating an external appearance obtained when a SiOx film is formed at about 200° C. and FIG. 3(b) is a photograph illustrating an external appearance obtained when a SiOx film is formed at about 300° C.

FIG. 4 includes photographs each obtained by observing a section using a TEM with a magnification of 200,000 times when a SiOx film is formed on a Cu single film by a CVD method at a film formation temperature of about 200° C. FIG. 4(a) is an overall view of a multilayer film and FIG. 4(b) is an enlarged view of a surface of the multilayer film

FIG. 5 is a photograph illustrating an external appearance obtained when a SiOx film is formed on a Cu-30 at % Ni/Cu multilayer film by a CVD method at a film formation temperature of 200° C.

FIG. 6 schematically illustrates wiring shapes obtained by a wet etching method. FIG. 6(a) illustrates a wiring shape in which a cap layer extends farther than a wiring layer and thus an extended portion is formed, FIG. 6(b) illustrates a reverse tapered wiring shape, and FIG. 6(c) illustrates a forward tapered wiring shape.

FIG. 7 is a schematic sectional view illustrating another structure of a multilayer wiring film according to the present invention.

### DESCRIPTION OF EMBODIMENTS

Hereafter, a multilayer wiring film according to the present invention will be described.

### (Multilayer Wiring Film)

A multilayer wiring film according to the present invention includes a wiring layer that has an electrical resistance of 10 μΩcm or less and is formed of Cu or a Cu alloy and a Cu—X alloy layer that is disposed above and/or below the wiring layer and contains Cu and an element X. The element X is at least one element selected from the group X consisting of Al, Mn, Zn, and Ni.

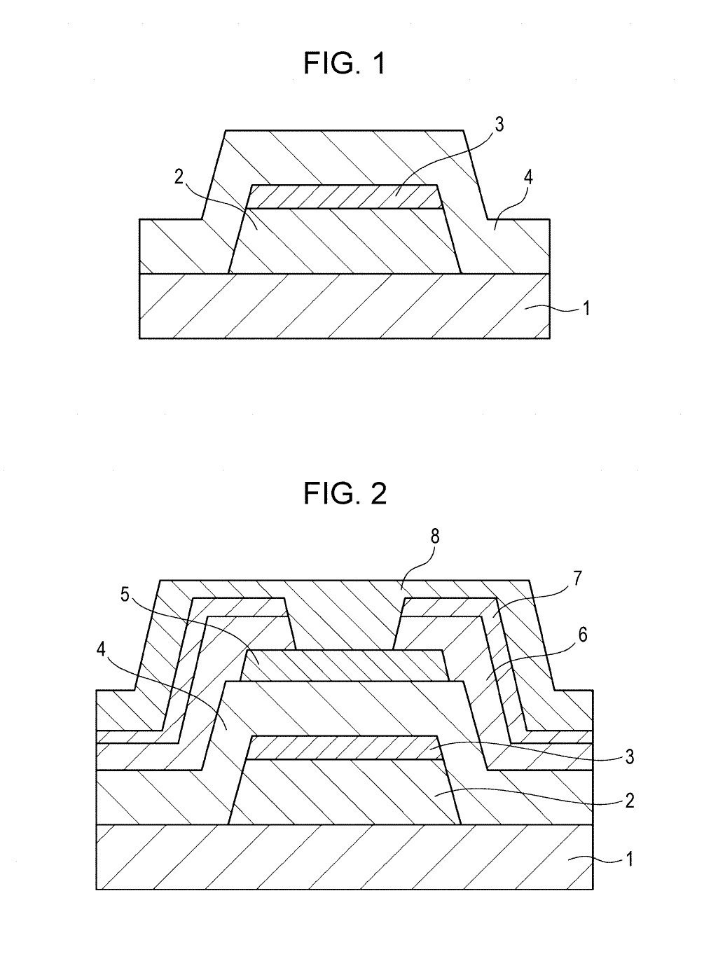

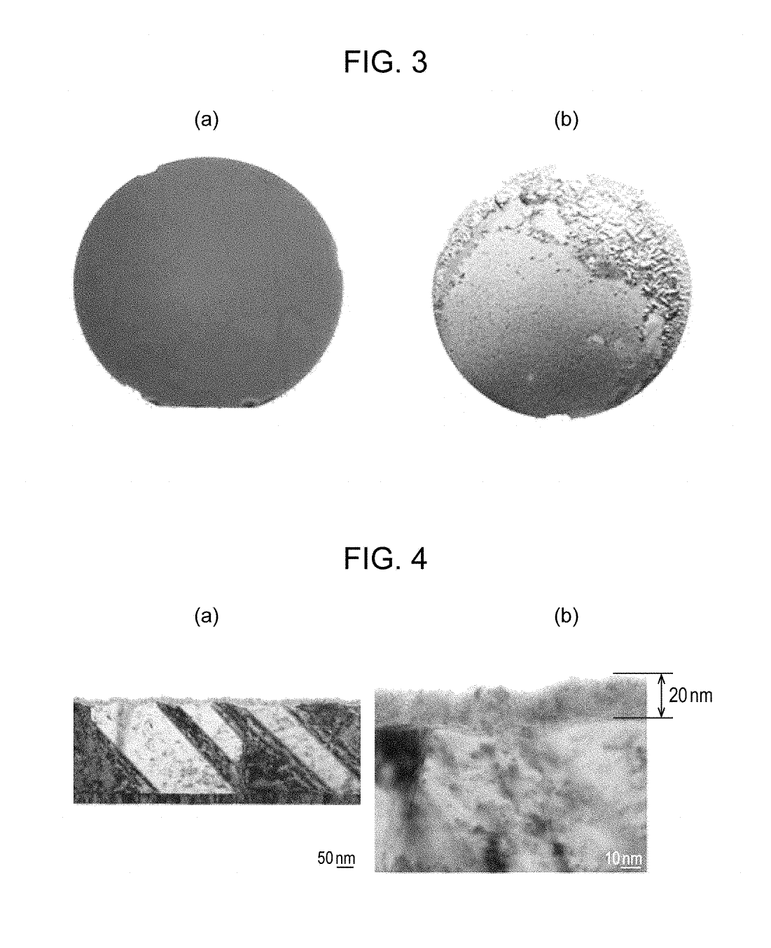

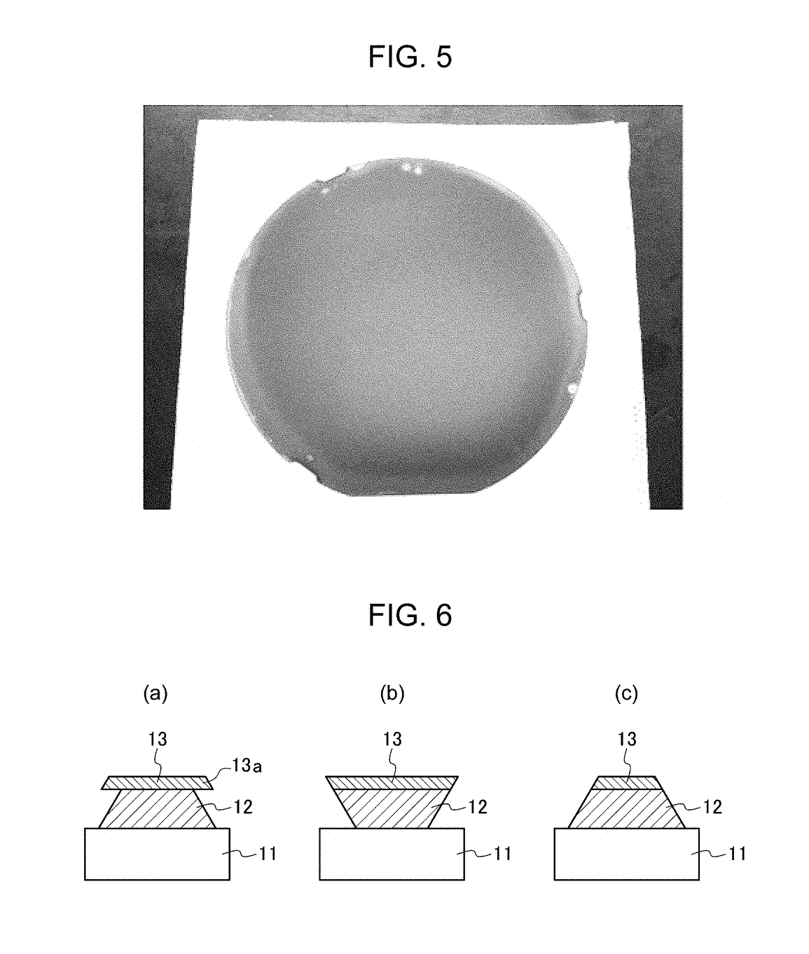

FIG. 1 is a schematic sectional view illustrating a structure of the multilayer wiring film according to the present invention. As illustrated in FIG. 1, in this embodiment, a multilayer wiring film including a wiring layer 2 and a cap layer (Cu—X alloy layer) 3 is laminated on a glass substrate 1 in this order, and an insulating film (SiOx) 4 is further formed on the multilayer wiring film. The insulating film (SiOx) 4 is, for example, a gate insulating film disposed between a gate electrode (Cu wiring) and an oxide semiconductor layer in a TFT.

### (Wiring Layer)

The wiring layer is a film formed of Cu or a Cu alloy Hereafter, such a film may be referred to as a “Cu-based film” When the wiring layer is formed as a conductive layer, the wiring layer is a Cu-based film having an electrical resistance of 10 μΩcm or less. When the electrical resistance of the wiring layer is 10 μΩcm or less, the multilayer wiring film can have a low electrical resistance. To further decrease the electrical resistance of the multilayer wiring film and improve the conductivity, the electrical resistance of the wiring layer is preferably 5 μΩcm or less and more preferably 4 μΩcm or less. Since Cu has a lower electrical resistance than a Cu alloy, the wiring layer is preferably formed of Cu.

The Cu alloy for forming the wiring layer is an alloy that contains at least one element Z selected from the group Z consisting of Ti, Mn, Fe, Co, Ni, Ge, and Zn, the balance being Cu and incidental impurities. When the Cu alloy contains the element Z, for example, corrosion resistance and adhesion to a substrate are improved. These elements Z may be used alone or in combination of two or more. The element Z can be contained, for example, in an amount of more than 0 at % and 2 at % or less in total.

The specifications of the electrode resistance are determined in consideration of performance required for panels. Therefore, the thickness of the wiring layer is preferably 50 nm or more, more preferably 70 nm or more, and further preferably 100 nm or more from the viewpoint of forming a film having a uniform thickness and component. On the other hand, the thickness of the wiring layer is preferably 1000 nm or less, more preferably 700 nm or less, and further preferably 500 nm or less from the viewpoint of ensuring productivity and etching workability.

### (Cu—X Alloy Layer)

The Cu—X alloy layer is disposed as a cap layer above and/or below the wiring layer. By disposing a cap layer on at least one surface of the wiring layer, an increase in electrical resistance of the Cu-based film can be suppressed even in a high-temperature heat treatment at 400° C. or higher and 500° C. or lower and film separation can be suppressed in the formation of a SiOx film.

The Cu—X alloy layer is formed of a Cu alloy containing Cu and an element X. The element X is at least one element selected from the group X consisting of Al, Mn, Zn, and Ni. The elements X may be used alone or in combination of two or more. The Cu alloy for forming the Cu—X alloy layer contains at least one element X selected from the group X consisting of Al, Mn, Zn, and Ni, the balance being Cu and incidental impurities.

In the present invention, the elements X of the metals constituting the Cu—X alloy layer have a composition represented by any one of (1) to (5) below.

(1) Only one element of the group X is contained in an amount of 6 at % or more and 27 at % or less.
(2) Al is contained in an amount of 4 at % or more and 15 at % or less and Mn is further contained in an amount of 5 at % or more and 10 at % or less.
(3) Zn is contained in an amount of 5 at % or more and 10 at % or less and Mn is further contained in an amount of 5 at % or more and 26 at % or less.
(4) Zn is contained in an amount of 4 at % or more and 14 at % or less and Al is further contained in an amount of 5 at % or more and 15 at % or less.
(5) Al is contained in an amount of 5 at % or more and 10 at % or less and Ni is further contained in an amount of 2 at % or more and 10 at % or less.

When the amount of the elements X contained in the Cu alloy for forming the Cu—X alloy layer is within the ranges of (1) to (5) above, the electrical resistance after heat treatment at 400° C. can be set to 3 μΩcm or less. If the amount of the elements X contained exceeds the above ranges, the resistance of an electrode after heat treatment at 400° C. sometimes exceeds 3 μΩcm. This is believed to be because the elements X diffuse into the wiring layer through the heat treatment.

The multilayer wiring film including the Cu—X alloy layer having the above composition can be suitably used as Cu wiring for TFT elements including an oxide semiconductor.

When heat treatment is performed at higher than 400° C. and 500° C. or lower, the elements X of the metals for synthesizing the Cu—X alloy layer preferably have a composition represented by any one of (1′) to (5′) below.

(1′) Only one element of the group X is contained in an amount of 6 at % or more and 14 at % or less.
(2′) Al is contained in an amount of 4 at % or more and 9 at % or less and Mn is further contained in an amount of 5 at % or more and 10 at % or less.
(3′) Zn is contained in an amount of 5 at % or more and 10 at % or less and Mn is further contained in an amount of 5 at % or more and 10 at % or less.
(4′) Zn is contained in an amount of 4 at % or more and 14 at % or less and Al is further contained in an amount of 5 at % or more and 10 at % or less.
(5′) Al is contained in an amount of 5 at % or more and 10 at % or less and Ni is further contained in an amount of 6 at % or more and 10 at % or less.

When the amount of the elements X contained in the Cu alloy for forming the Cu—X alloy layer is within the ranges (1′) to (5′) above, the electrical resistance even after heat treatment at 500° C. can be set to 3 μΩcm or less.

The multilayer wiring film including the Cu—X alloy layer having the above composition can be suitably used as Cu wiring for TFT elements including an oxide semiconductor or an LTPS semiconductor.

When a Cu—Mn film is heated in an oxidative atmosphere or in the oxygen plasma, a Mn element diffuses to the alloy surface to form a concentrated layer. The concentrated manganese is oxidized to cause passivation. Therefore, elements other than a Cu element that has been oxidized at the beginning of the reaction are protected by the passivation layer of Mn oxide. As a result, oxygen does not further diffuse to the inside of the Cu—Mn film, which suppresses progress of oxidation. Herein, if the Mn content falls below the predetermined range, a concentrated layer capable of suppressing oxidation sometimes cannot be formed. If the Mn content exceeds the predetermined range, the etching of the Cu—Mn film is facilitated during wiring formation that uses a hydrogen peroxide solution or a mixed acid-based etchant in the process of thin film transistors. Thus, a good wiring shape is sometimes not obtained.

When the elements X are Al and Zn, passivation is caused as in the case of Mn and the surface of Cu is also protected from oxidation. For these elements X, however, when a hydrogen peroxide solution or a mixed acid-based etchant is used, Al inhibits etching and Zn facilitates etching. When these elements are added, the amount of Al added is not preferably increased to a predetermined amount or more because the etching rate is lower in the Cu—X alloy layer than in the wiring layer, the Cu—X alloy layer extends farther than the wiring layer, and the extended portion is left. If the amount of Zn added is increased to a predetermined amount or more, the etching rate of the Cu—X alloy layer is further increased and thus a good etching profile is sometimes not obtained.

When the element X is Ni, the Ni content does not preferably fall below the predetermined range because protection from oxidation is not sufficiently provided. Ni is also an element that is easily dissolved in Cu and diffuses into Cu or a Cu alloy laminated as a wiring layer as a result of heating. The Ni content does not preferably exceed the predetermined range because the resistance increases as a result of the diffusion after heat treatment.

When the multilayer wiring film including the Cu—X alloy layer having the above composition is laminated on a substrate, the multilayer wiring film preferably further includes an adhesive layer containing Ti on a surface that is closer to the substrate. To improve the adhesion between the semiconductor substrate (insulator) and the wiring layer (Cu metal), an adhesive layer containing Ti (e.g., elemental Ti, Ti alloy, Ti oxide, and Ti nitride) is sometimes disposed between the semiconductor substrate and the wiring layer. However, Ti may diffuse into Cu as a result of high-temperature heat treatment during formation of a SiOx film, which may increase the wiring resistance. In contrast, when the multilayer wiring film includes a cap layer formed of the above-described particular alloy layer, the diffusion of Ti into Cu can be suppressed, which can suppress an increase in wiring resistance.

Although the reason for this is unclear, it is believed that since diffusion of Ti is driven by oxygen, the entry of oxygen into the wiring layer (Cu wiring film) is inhibited by laminating the cap layer according to the present invention.

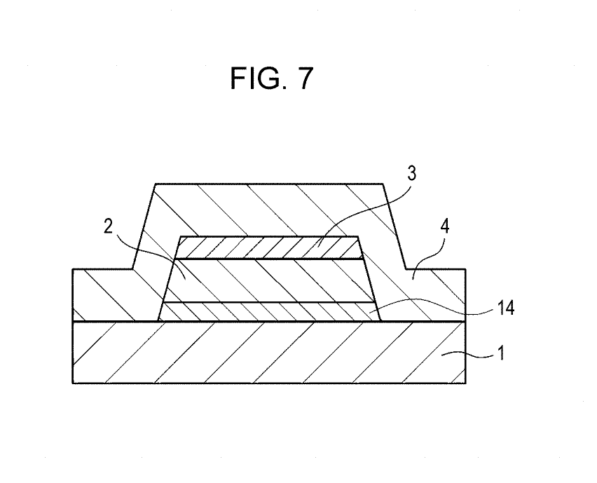

FIG. 7 is a schematic sectional view illustrating a structure of a multilayer wiring film including an adhesive layer containing Ti. As illustrated in FIG. 7, in this embodiment, a multilayer wiring film including an adhesive layer 14, a wiring layer 2, and a cap layer (Cu—X alloy layer) 3 is laminated on a glass substrate 1 in this order, and an insulating film (SiOx) 4 is further formed on the multilayer wiring film. In this embodiment, a cap layer 3 may be further disposed between the adhesive layer 14 and the wiring layer 2. Alternatively, the adhesive layer 14, the cap layer 3, and the wiring layer 2 may be laminated on the glass substrate 1 in this order.

The thickness of the adhesive layer is preferably 10 nm or more, more preferably 15 nm or more, and further preferably 20 nm or more. The thickness of the adhesive layer is preferably 50 nm or less, more preferably 40 nm or less, and further preferably 30 nm or less. When the thickness of the adhesive layer is within the above range, the adhesive layer can be uniformly formed between the wiring layer and the substrate, which can provide good adhesion of films

If the Cu—X alloy layer has a small thickness, oxidation resistance is not sufficiently provided. If the Cu—X alloy layer has a large thickness, the etching workability is impaired and the resistance of a Cu electrode as a whole is increased. Therefore, the thickness of the Cu—X alloy layer is preferably 5 nm or more and 200 nm or less. The thickness of the Cu—X alloy layer is preferably 10 nm or more and further preferably 20 nm or more. The thickness is more preferably 150 nm or less and further preferably 100 nm or less.

The total thickness of the wiring layer and the Cu—X alloy layer, that is, the thickness of the multilayer wiring film is preferably 55 nm or more, more preferably 70 nm or more, and further preferably 100 nm or more. The total thickness is preferably 1200 nm or less, more preferably 700 nm or less, and further preferably 500 nm or less. When the thickness of the multilayer wiring film is within the above range, the multilayer wiring film can be formed at low cost and a good wiring shape can be obtained.

In the multilayer wiring film according to the present invention, the wiring shape is preferably a forward tapered shape illustrated in FIG. 6(c). When the wiring shape is a forward tapered shape unlike a shape in which the Cu—X alloy layer extends farther than the wiring layer, the breakage of an interlayer insulating film and wiring lines formed on the Cu—X alloy layer can be suppressed.

The taper angle of the wiring layer is preferably 100° or less, more preferably 30° to 80°, more preferably 30° to 60°, and further preferably 40° to 60° relative to the substrate. When the taper angle of the wiring layer is within the above range, the width of a wiring layer exposed at the taper end of the multilayer wiring film can be decreased. If the taper angle is small and thus the width of a wiring layer exposed is large, the area of a wiring layer not protected by the cap layer increases and oxidation may occur in the subsequent process. If the taper end is oxidized, the width of a wiring layer that functions as a wiring line having a low electrical resistance decreases, which may increase the wiring resistance.

The taper angle of the wiring layer is preferably in the range of −25% to +50% relative to the taper angle of a Cu single-layer film having the same thickness. When the taper angle of a wiring layer relative to the taper angle of a Cu single-layer film having the same thickness is within the above range, the breakage of an interlayer insulating film and wiring lines formed on the Cu—X alloy layer can be further suppressed.

In the present invention, the wiring layer and the Cu—X alloy layer are preferably formed by a sputtering method. The sputtering method is excellent in terms of productivity. By using a sputtering target, an alloy film having substantially the same composition can be stably formed. Examples of the sputtering method that may be employed include a DC sputtering method, an RF sputtering method, a magnetron sputtering method, and a reactive sputtering method. The formation conditions can be appropriately set.

For example, when the Cu—X alloy layer is formed by the sputtering method, a Cu alloy sputtering target that is made of a Cu alloy containing a predetermined amount of element X and has the same composition as a desired Cu—X alloy layer is used as the target. Thus, a Cu—X alloy layer having a desired composition can be formed without causing composition unevenness. Alternatively, discharge may be simultaneously performed on two or more pure metal targets or alloy targets having different compositions to cause film formation. Alternatively, film formation may be performed while the composition is adjusted by placing chips of metals of alloy elements on a pure Cu target.

When the Cu—X alloy layer is formed by a sputtering method, for example, the following sputtering conditions are employed. (sputtering conditions)

Sputtering apparatus: DC magnetron sputtering apparatus (“CS-200” manufactured by ULVAC, Inc.)

Substrate: alkali-free glass (“Eagle 2000” manufactured by Corning)

Substrate temperature: room temperature

Film formation gas: Ar gas

Gas pressure: 2 mTorr

Sputtering power: 300 W

Ultimate vacuum: 1×10⁻⁶ Torr or less

The Cu alloy sputtering target according to the present invention may have any shape such as a rectangular plate shape, a circular plate shape, or a doughnut plate shape in accordance with the shape or structure of the sputtering apparatus. Examples of a method for producing the Cu alloy sputtering target include methods for obtaining the target by producing a Cu alloy ingot through a melt casting method, a powder sintering method, or a spray forming method, and methods for obtaining the target by producing a preform formed of a Cu alloy, that is, an intermediate product provided before a compact end product and then compacting the preform by compacting means.

The wiring pattern can be formed by performing treatment such as etching on the multilayer wiring film according to the present invention. By finely forming the wiring pattern, the aperture ratio of pixel elements can be increased. Thus, high-definition display devices can be provided. TFT elements including an oxide semiconductor or a low temperature poly-silicon semiconductor are incorporated in high-definition panels and are therefore required to decrease the wiring width. From this viewpoint, the specific width of the wiring pattern is preferably 10 μm or less and more preferably 5 μm or less.

Each layer other than the Cu—X alloy layer can be appropriately formed by a method that is typically used in the technical field of the present invention.

The multilayer wiring film according to the present invention can be applied to wiring electrodes and input devices. The input devices are classified into input devices such as touch panels in which input means is included in a display device and input devices such as touch pads which do not include a display device. The multilayer wiring film according to the present invention is particularly preferably used for touch panel sensors.

Next, a thin film transistor element according to the present invention will be described.

### (Thin Film Transistor Element)

The thin film transistor element according to the present invention includes a multilayer wiring film that includes a wiring layer having an electrical resistance of 10 μΩcm or less and formed of Cu or a Cu alloy and that includes a Cu—X alloy layer disposed above and/or below the wiring layer and containing Cu and an element X. The element X is at least one element selected from the group X consisting of Al, Mn, Zn, and Ni. Furthermore, an oxide semiconductor or an LTPS semiconductor is used for an active layer of TFTs.

FIG. 2 is a schematic sectional view illustrating a structure of a thin film transistor element including the multilayer wiring film according to the present invention. As illustrated in FIG. 2, in this embodiment, a multilayer wiring film including a wiring layer 2 and a cap layer (Cu—X alloy layer) 3, an insulating film (SiOx) 4, an oxide semiconductor 5, a multilayer wiring film including a wiring layer 6 and a cap layer (Cu—X alloy layer) 7, and an insulating film (SiOx) 8 are laminated on a glass substrate 1 in this order. The above-described particular alloy layer is suitably used as the cap layer (Cu—X alloy layer) 3 and the cap layer (Cu—X alloy layer) 7.

### EXAMPLES

Hereafter, the present invention will be more specifically described based on Examples and Comparative Examples. The present invention is not limited to Examples below, and can be modified without departing from the spirit of the present invention. Such modifications are within the technical scope of the present invention.

### Example 1

### (1) Production of Multilayer Wiring Film

An alkali-free glass plate having a diameter of 4 inches and a thickness of 0.7 mm was provided as a transparent substrate. The alkali-free glass plate was washed with a neutral detergent and then subjected to irradiation with an excimer UV lamp for 30 minutes to remove contamination on the surface. A multilayer wiring film including a wiring layer and a cap layer serving as a Cu—X alloy layer in Table 1 was formed on the surface-treated alkali-free glass plate by a DC magnetron sputtering method. The wiring film of the sample No. 1 was a single-layer film including only a wiring layer.

The atmosphere in a chamber was adjusted to 3×10⁻⁶ Torr once before film formation. Then, a wiring layer and a cap layer were formed on the substrate in this order by performing sputtering under the following sputtering conditions to form a multilayer wiring film. The sputtering target was a pure Cu sputtering target or a target having the same composition as the corresponding cap layer, each of which was a disc-shaped sputtering target having a diameter of 4 inches. The evaluations below were performed using the produced multilayer wiring film.

### (Sputtering Conditions)

Sputtering apparatus: DC magnetron sputtering apparatus (“CS-200” manufactured by ULVAC, Inc.)

Substrate: alkali-free glass plate (“Eagle 2000” manufactured by Corning)

Substrate temperature: room temperature

Film formation gas: Ar gas

Gas pressure: 2 mTorr

Sputtering power: 300 W

Ultimate vacuum: 1×10⁻⁶ Torr or less

### (2) Measurement of Electrical Resistivity of Multilayer Wiring Film

The electrical resistivity of the multilayer wiring film was measured as follows. That is, the electrical resistance of a sample in which a Cu-based film shown in Table 1 was formed on the alkali-free glass plate and a cap layer having a thickness shown in Table 1 was formed on the Cu-based film was measured by a four-terminal method. The electrical resistivity was calculated from the measured electrical resistance and the total thickness of the Cu-based film and the cap layer. Then, after heat treatment at 400° C. for one hour and heat treatment at 500° C. for one hour were performed in a N₂ atmosphere using an infrared lamp heater RTP-6 manufactured by ULVAC, Inc., the electrical resistance was measured in the same manner and the electrical resistivity was calculated in the same manner.

Table 1 shows the results. In Examples, samples having an electrical resistivity of 3 μΩcm or less at 400° C. were evaluated to be good in terms of heat resistance for TFT elements including an oxide semiconductor, and samples having an electrical resistivity of 3 μΩcm or less at 500° C. were evaluated to be good in terms of heat resistance for TFT elements including an oxide semiconductor or an LTPS semiconductor.

### (3) Evaluation of Wiring Shape and Taper Angle

A resist pattern constituted by lines and spaces were formed on the multilayer wiring film using a photoresist. The multilayer wiring films of the sample Nos. 2 to 39 were each etched with a hydrogen peroxide-based etchant manufactured by Mitsubishi Gas Chemical Company, Inc. Then, the multilayer wiring film was immersed in acetone to remove the resist and cleaved together with the transparent substrate. Subsequently, the sectional shape of the etched sample was observed with an electron microscope S-4000 manufactured by Hitachi Power Solutions Co., Ltd. As illustrated in FIG. 6(a), samples in which the cap layer 13 extended farther than the wiring layer 12 and thus an extended portion 13a was formed were evaluated to be “extended portion”. As illustrated in FIG. 6(b), samples having a reverse tapered shape were evaluated to be “reverse tapered”. As illustrated in FIG. 6(c), samples having a forward tapered shape were evaluated to be “forward tapered”.

Subsequently, the taper angle relative to the transparent substrate was measured from the sectional shape for each of the multilayer wiring films of the sample Nos. 1 to 39. Furthermore, the ratio of the taper angle of a wiring layer to the taper angle of a Cu single film in the sample No. 1 produced by the same method was calculated from formula (1) below. Herein, samples in which the taper angle relative to the transparent substrate was 30° to 80° were evaluated to be good. In particular, samples in which the ratio of the taper angle of a wiring layer to the taper angle of a Cu single film in the sample No. 1 was in the range of −25% to +50% were evaluated to be excellent. Table 1 shows the results.

Ratio (%) of taper angle relative to taper angle of Cu single film=[(taper angle of Cu single film)−(taper angle of multilayer wiring film)]/(taper angle of Cu single film) (1)

### (4) Evaluation of Oxidation Resistance

A SiOx film was formed on the cap layer of the multilayer wiring film using a plasma CVD apparatus PD-220 ML manufactured by Samco Inc. A SiOx film having a thickness of 250 nm was formed by using SiH₄ and N₂O gases, and the external appearance was visually inspected to confirm whether the SiOx film was separated or not. Table 1 shows the results. In the case where the oxidation resistance is insufficient, the film surface is oxidized during formation of the SiOx film, which undesirably causes color unevenness and separation of the SiOx film due to volume expansion of interfaces.

Table 1 shows the results of (2) the measurement of the electrical resistivity of the multilayer wiring film, (3) the evaluation of the wiring shape and the taper angle, and (4) the evaluation of the oxidation resistance.

From the results of (2) to (4), samples in which the electrical resistivity after heat treatment at 400° C. is 3 μΩcm or less, the wiring shape is a forward tapered shape, and film separation does not occur during formation of the SiOx film by a CVD method are suitable for TFT elements including an oxide semiconductor and are evaluated to be “Good”. Samples in which any one of the above conditions is not satisfied are evaluated to be “Poor”.

In addition, samples in which the electrical resistivity after heat treatment at 400° C. and 500° C. is 3 μΩcm or less, the wiring shape is a forward tapered shape, the taper angle relative to the transparent substrate is 30° to 80°, and film separation does not occur during formation of the SiOx film by a CVD method are suitable for TFT elements including an oxide semiconductor or a low temperature poly-silicon semiconductor and are evaluated to be “Good”. Samples in which any one of the above conditions is not satisfied are evaluated to be “Poor”.

Table 1 collectively shows the results.

TABLE 1

| | | | Lamination | | | | | | | Ratio of taper | Film separation | For TFT | For TFT |
|---|---|---|---|---|---|---|---|---|---|---|---|---|---|
| | | | thickness | | Electrical resistance μΩcm | | | | | angle of | during | element | element |
| | Film structure | | nm | | Immediately | After heat | After heat | | | wiring layer to | formation of | including | including |
| | | Wiring | Cap | Wiring | after film | treatment | treatment | | Taper angle | Cu single film | SiOx film by | oxide | LTPS |
| No. | Cap layer | layer | layer | layer | formation | at 400° C. | at 500° C. | Wiring shape | (°) | (%) | CVD | semiconductor | semiconductor |
| 1 | — | Cu | — | 330 | — | — | — | forward tapered | 40 | 0 | Yes | Poor | Poor |
| 2 | Cu—5 at % Ni | Cu | 30 | 300 | — | 2.1 | 2.5 | forward tapered | 60 | 50 | Yes | Poor | Poor |
| 3 | Cu—30 at % Ni | Cu | 30 | 300 | 2.2 | 2.7 | 4.1 | extended portion | 77 | 92.5 | No | Poor | Poor |
| 4 | Cu—5.5 at % Al | Cu | 30 | 300 | 2.3 | 1.8 | 1.8 | forward tapered | 63 | 57.5 | Yes | Poor | Poor |
| 5 | Cu—7 at % Al | Cu | 30 | 300 | 2.2 | 1.9 | 1.9 | forward tapered | 57 | 42.5 | No | Good | Good |
| 6 | Cu—27.2 at % Al | Cu | 30 | 300 | 2.3 | 3.1 | 3.9 | No evaluation | No evaluation | No evaluation | No | Poor | Poor |
| 7 | Cu—5.5 at % Mn | Cu | 30 | 300 | 2.2 | 1.9 | 1.9 | forward tapered | 46 | 15 | Yes | Poor | Poor |
| 8 | Cu—13.7 at % Mn | Cu | 30 | 300 | 2.2 | 2.2 | 2.0 | forward tapered | 33 | −17.5 | No | Good | Good |
| 9 | Cu—17.9 at % Mn | Cu | 30 | 300 | 2.2 | 2.2 | 2.0 | forward tapered | 26 | −35 | No | Good | Poor |
| 10 | Cu—23.8 at % Mn | Cu | 30 | 300 | 2.2 | 2.2 | 2.0 | forward tapered | 17 | −57.5 | No | Good | Poor |
| 11 | Cu—5.1 at % Sn | Cu | 30 | 300 | 2.2 | 2.2 | 2.2 | forward tapered | 43 | 7.5 | Yes | Poor | Poor |
| 12 | Cu—4.0 at % Zn | Cu | 30 | 300 | 2.2 | 2.2 | 2.1 | forward tapered | 19 | −52.5 | Yes | Poor | Poor |
| 13 | Cu—26.4 at % Zn | Cu | 30 | 300 | 2.2 | 2.6 | 2.3 | forward tapered | 8 | −80 | No | Good | Poor |
| 14 | Cu—3 at % Al—20 at % Mn | Cu | 30 | 300 | 2.2 | 3.4 | 3.5 | forward tapered | 21 | −47.5 | No | Poor | Poor |
| 15 | Cu—5 at % Al—20 at % Mn | Cu | 30 | 300 | 2.2 | 4.3 | 4.5 | forward tapered | 24 | −40 | No | Poor | Poor |
| 16 | Cu—5 at % Al—15 at % Mn | Cu | 30 | 300 | 2.2 | 3.7 | 4.8 | forward tapered | 27 | −32.5 | No | Poor | Poor |
| 17 | Cu—5 at % Al—26 at % Mn | Cu | 30 | 300 | 2.3 | 4.4 | 4.7 | forward tapered | 21 | −47.5 | No | Poor | Poor |
| 18 | Cu—10 at % Al—26 at % Mn | Cu | 30 | 300 | 2.2 | 4.8 | 6.8 | forward tapered | 31 | −22.5 | No | Poor | Poor |
| 19 | Cu—5 at % Al—5.5 at % Mn | Cu | 30 | 300 | 2.1 | 1.9 | 2.7 | forward tapered | 35 | −12.5 | No | Good | Good |
| 20 | Cu—10 at % Al—5.5 at % Mn | Cu | 30 | 300 | 2.1 | 2.7 | 3.3 | forward tapered | 65 | 62.5 | No | Good | Poor |
| 21 | Cu—15 at % Al—5.5 at % Mn | Cu | 30 | 300 | 2.1 | 2.9 | 3.6 | forward tapered | 61 | 52.5 | No | Good | Poor |
| 22 | Cu—5 at % Zn—26 at % Mn | Cu | 30 | 300 | 2.3 | 2.0 | 2.1 | forward tapered | 16 | −60 | No | Good | Poor |
| 23 | Cu—7 at % Zn—26 at % Mn | Cu | 30 | 300 | 2.2 | 2.0 | 2.1 | forward tapered | 12 | −70 | No | Good | Poor |
| 24 | Cu—5 at % Zn—5 at % Mn | Cu | 30 | 300 | 2.1 | 1.9 | 1.9 | forward tapered | 24 | −40 | No | Good | Poor |
| 25 | Cu—10 at % Zn—5 at % Mn | Cu | 30 | 300 | 2.0 | 2.0 | 2.0 | forward tapered | 22 | −45 | No | Good | Poor |
| 26 | Cu—5 at % Zn—10 at % Mn | Cu | 30 | 300 | 2.1 | 2.0 | 1.9 | forward tapered | 21 | −47.5 | No | Good | Poor |
| 27 | Cu—7.8 at % Zn—5.6 at % Al | Cu | 30 | 300 | 2.2 | 2.1 | 2.0 | forward tapered | 31 | −22.5 | No | Good | Good |
| 28 | Cu—7.0 at % Zn—10.0 at % Al | Cu | 30 | 300 | 2.2 | 2.4 | 2.4 | forward tapered | 30 | −25 | No | Good | Good |
| 29 | Cu—9.8 at % Zn—10.0 at % Al | Cu | 30 | 300 | 2.2 | 2.4 | 2.5 | forward tapered | 49 | 22.5 | No | Good | Good |
| 30 | Cu—10.0 at % Zn—10.0 at % Al | Cu | 30 | 300 | 2.1 | 2.4 | 2.5 | forward tapered | 47 | 17.5 | No | Good | Good |
| 31 | Cu—14.0 at % Zn—15.0 at % Al | Cu | 30 | 300 | 2.2 | 2.8 | 3.0 | forward tapered | 82 | 105 | No | Good | Poor |
| 32 | Cu—4.3 at % Zn—6.9 at % Al | Cu | 30 | 300 | 2.3 | 2.0 | 2.1 | forward tapered | 39 | −2.5 | No | Good | Good |
| 33 | Cu—5.6 at % Zn—7.0 at % Al | Cu | 30 | 300 | 2.3 | 2.0 | 2.0 | forward tapered | 39 | −2.5 | No | Good | Good |
| 34 | Cu—7.0 at % Zn—7.0 at % Al | Cu | 30 | 300 | 2.2 | 2.0 | 2.0 | forward tapered | 39 | −2.5 | No | Good | Good |
| 35 | Cu—7.0 at % Al—3.0 at % Ni | Cu | 30 | 500 | 2.2 | 2.3 | 2.4 | forward tapered | 65 | 62.5 | No | Good | Good |
| 36 | Cu—7.0 at % Al—5.0 at % Ni | Cu | 30 | 500 | 2.3 | 2.3 | 2.4 | forward tapered | 69 | 72.5 | No | Good | Good |
| 37 | Cu—7.0 at % Al—7.0 at % Ni | Cu | 30 | 500 | 2.3 | 2.3 | 2.3 | forward tapered | 73 | 82.5 | No | Good | Good |
| 38 | Cu—7.0 at % Al—10.0 at % Ni | Cu | 30 | 500 | 2.3 | 2.3 | 2.3 | forward tapered | 77 | 92.5 | No | Good | Good |
| 39 | Cu—10.0 at % Al—5.0 at % Ni | Cu | 30 | 500 | 2.3 | 2.3 | 2.4 | forward tapered | 65 | 62.5 | No | Good | Good |

The following is found from the results in Table 1. The sample No. 1 was an example of a Cu single film without a cap layer, and film separation was observed during formation of the SiOx film. In the sample Nos. 2 to 13, the Cu—X alloy layer serving as a cap layer of the multilayer wiring film contained Cu and one element. In the sample Nos. 5, 8 to 10, and 13 in which the composition (1) of elements X of the Cu—X alloy layer specified in the present invention was satisfied, the wiring shape was a forward tapered shape, the electrical resistance after heat treatment at 400° C. was 3 μΩcm or less, and film separation was not observed during formation of the SiOx film. In contrast, in the sample Nos. 3 and 6, a low electrical resistance was not stably achieved after high-temperature heat treatment. The sample No. 3 also had a wiring shape in which an extended portion was formed in the Cu—X alloy layer. In the sample Nos. 2, 4, 7, 11, and 12, film separation was observed during formation of the SiOx film

In particular, in the sample Nos. 5 and 8 in which the composition (1′) of elements X of the Cu—X alloy layer specified in the present invention was satisfied, the wiring shape was a forward tapered shape, the taper angle was 30° to 80°, the electrical resistance after heat treatment at each of 400° C. and 500° C. was 3 μΩcm or less, and film separation was not observed during formation of the SiOx film

In the sample Nos. 14 to 39, the Cu—X alloy layer serving as a cap layer of the multilayer wiring film contained Cu and two or more elements. In the sample Nos. 19 to 39 in which any one of the compositions (2) to (5) of elements X of the Cu—X alloy layer specified in the present invention was satisfied, the wiring shape was a forward tapered shape, the electrical resistance after heat treatment at 400° C. was 3 μΩcm or less, and film separation was not observed during formation of the SiOx film. In contrast, in the sample Nos. 14 to 18, a low electrical resistance was not stably achieved after high-temperature heat treatment.

In particular, in the sample Nos. 19, 27 to 30, and 32 to 39 in which any one of the compositions (2′) to (5′) of elements X of the Cu—X alloy layer specified in the present invention was satisfied, the wiring shape was a forward tapered shape, the taper angle was 30° to 80°, the electrical resistance after heat treatment at each of 400° C. and 500° C. was 3 μΩcm or less, and film separation was not observed during formation of the SiOx film.

Focusing on the Cu—Zn—Mn alloy layers of the sample Nos. 22 to 26, in the sample Nos. 24 to 26 in which the composition (3′) of elements X of the Cu—X alloy layer specified in the present invention was satisfied, the electrical resistance (2.0 μΩcm or less) after heat treatment at 500° C. was lower than that in the sample Nos. 22 and 23. This result shows that the Mn content in the case where the Cu—Zn—Mn alloy layer is used is preferably 10 at % or less.

Similarly, focusing on the Cu—Al—Ni alloy layers of the sample Nos. 35 to 39, in the sample Nos. 37 and 38 in which the composition (5′) of elements X of the Cu—X alloy layer specified in the present invention was satisfied, the electrical resistance (2.3 μΩcm) after heat treatment at 500° C. was lower than that in the sample Nos. 35, 36, and 39. This result shows that the Ni content in the case where the Cu—Al—Ni alloy layer is used is preferably 6 at % or more.

### Example 2

A multilayer wiring film using an adhesive layer containing Ti was produced through the following procedure. Specifically, as in Example 1, a multilayer wiring film including an adhesive layer, a wiring layer, and a cap layer serving as a Cu—X alloy layer in Table 2 was sequentially formed on the alkali-free glass plate serving as a transparent substrate by a DC magnetron sputtering method. The wiring film of the sample No. 40 is a multilayer film including only an adhesive layer and a wiring layer. The film formation conditions for the adhesive layer, the wiring layer, and the cap layer were the same as those in Example 1.

For the produced multilayer wiring films, the measurement of electrical resistivity and the evaluation of oxidation resistance were performed under the same conditions as those in Example 1. From the above results, samples in which the electrical resistivity after heat treatment at 400° C. is 3 μΩcm or less and film separation does not occur during formation of the SiOx film by a CVD method are suitable for TFT elements including an oxide semiconductor and are evaluated to be “Good”. Samples in which any one of the above conditions is not satisfied are evaluated to be “Poor”.

In addition, samples in which the electrical resistivity after heat treatment at each of 400° C. and 500° C. is 3 μΩcm or less and film separation does not occur during formation of the SiOx film by a CVD method are suitable for TFT elements including an oxide semiconductor or a low temperature poly-silicon semiconductor and are evaluated to be “Good”. Samples in which any one of the above conditions is not satisfied are evaluated to be “Poor”.

Table 2 collectively shows the results of the measurement of the electrical resistivity of the multilayer wiring film, the evaluation of the oxidation resistance, and the suitability for TFT elements including an oxide semiconductor or a low temperature poly-silicon semiconductor.

TABLE 2

| | | | | | | | | | | Film | | |
|---|---|---|---|---|---|---|---|---|---|---|---|---|
| | | | | | | | | | | separation | For TFT | For TFT |
| | | | | | | | | | | during | element | element |
| | | | | Lamination | | | Electrical resistance μΩcm | | | formation | including | including |
| | Film structure | | | thickness nm | | | Immediately | After heat | After heat | of SiOx | oxide | LTPS |
| | | Wiring | Adhesive | Cap | Wiring | Adhesive | after film | treatment | treatment | film by | semi- | semi- |
| No. | Cap layer | layer | layer | layer | layer | layer | formation | at 400° C. | at 500° C. | CVD | conductor | conductor |
| 40 | — | Cu | Ti | 30 | 500 | 20 | 2.2 | 2.8 | 3.3 | Yes | Poor | Poor |
| 41 | Cu—30 at % Ni | Cu | Ti | 30 | 500 | 20 | 2.2 | 3.2 | 4.8 | No | Poor | Poor |
| 42 | Cu—7 at % Al | Cu | Ti | 30 | 500 | 20 | 2.5 | 2.5 | 2.5 | No | Good | Good |
| 43 | Cu—10 at % Al | Cu | Ti | 30 | 500 | 20 | 2.2 | 2.6 | 2.8 | No | Good | Good |
| 44 | Cu—4.3 at | Cu | Ti | 30 | 500 | 20 | 2.2 | 2.4 | 2.5 | No | Good | Good |
| | % Zn—6.9 | | | | | | | | | | | |
| | at % Al | | | | | | | | | | | |
| 45 | Cu—7 at | Cu | Ti | 30 | 500 | 20 | 2.3 | 2.3 | 2.5 | No | Good | Good |
| | % Al—5 at | | | | | | | | | | | |
| | % Ni | | | | | | | | | | | |
| 46 | Cu—7 at | Cu | Ti | 30 | 500 | 20 | 2.3 | 2.3 | 2.3 | No | Good | Good |
| | % Al—10 at | | | | | | | | | | | |
| | % Ni | | | | | | | | | | | |

The following is found from the results in Table 2. The sample No. 40 was an example of a multilayer film including only an adhesive layer and a wiring layer, and film separation was observed during formation of the SiOx film. Furthermore, the electrical resistance after heat treatment at 500° C. was outside the range of 3 μΩcm or less. In the sample No. 41 in which the composition (1) of elements X of the Cu—X alloy layer specified in the present invention was not satisfied, film separation was not observed during formation of the SiOx film, but the electrical resistance after heat treatment at each of 400° C. and 500° C. was outside the range of 3 μΩcm or less.

In contrast, in the sample Nos. 42 to 46 in which any one of the compositions (1) to (5) of elements X of the Cu—X alloy layer specified in the present invention was satisfied, the electrical resistance after heat treatment at each of 400° C. and 500° C. was 3 μΩcm or less and film separation was not observed during formation of the SiOx film

The present invention has been described in detail based on specific embodiments. However, it is obvious for those skilled in the art that various modifications and alterations can be made without departing from the spirit and scope of the present invention. This application is based on Japanese Patent Application No. 2016-097321 filed on May 13, 2016 and Japanese Patent Application No. 2017-078505 filed on Apr. 11, 2017, the entire contents of which are incorporated herein by reference.

### REFERENCE SIGNS LIST

1 glass substrate
2 wiring layer
3 cap layer (Cu—X alloy layer)
4 insulating film (SiOx)
5 oxide semiconductor
6 wiring layer
7 cap layer (Cu—X alloy layer)
8 insulating film (SiOx)
11 substrate
12 wiring layer
13 cap layer
13a extended portion
14 adhesive layer

1. A multilayer wiring film comprising a wiring layer that has an electrical resistance of 10 μΩcm or less and is formed of Cu or a Cu alloy and a Cu—X alloy layer that is disposed above and/or below the wiring layer and contains Cu and an element X,
wherein the element X is at least one element selected from the group X consisting of Al, Mn, Zn, and Ni,
metals constituting the Cu—X alloy layer have a composition represented by any one of (2) to (5) below, and
a wiring pattern has a width of 10 μm or less:
(2) Al is contained in an amount of 4 at % or more and 15 at % or less and Mn is further contained in an amount of 5 at % or more and 10 at % or less,
(3) Zn is contained in an amount of 5 at % or more and 10 at % or less and Mn is further contained in an amount of 5 at % or more and 26 at % or less,
(4) Zn is contained in an amount of 4 at % or more and 14 at % or less and Al is further contained in an amount of 5 at % or more and 15 at % or less, and
(5) Al is contained in an amount of 5 at % or more and 10 at % or less and Ni is further contained in an amount of 2 at % or more and 10 at % or less.

2. The multilayer wiring film according to claim 1,
wherein metals constituting the Cu—X alloy layer have a composition represented by any one of (2′) to (5′) below, and
a wiring pattern has a width of 5 μm or less:
(2′) Al is contained in an amount of 4 at % or more and 9 at % or less and Mn is further contained in an amount of 5 at % or more and 10 at % or less,
(3′) Zn is contained in an amount of 5 at % or more and 10 at % or less and Mn is further contained in an amount of 5 at % or more and 10 at % or less,
(4′) Zn is contained in an amount of 4 at % or more and 14 at % or less and Al is further contained in an amount of 5 at % or more and 10 at % or less, and
(5′) Al is contained in an amount of 5 at % or more and 10 at % or less and Ni is further contained in an amount of 6 at % or more and 10 at % or less.

3. The multilayer wiring film according to claim 1, wherein the multilayer wiring film is laminated on a substrate, and the multilayer wiring film further comprises an adhesive layer containing Ti on a surface that is closer to the substrate.

4. The multilayer wiring film according to claim 1, wherein the wiring layer has a thickness of 50 nm or more and 1000 nm or less, and the Cu—X alloy layer has a thickness of 5 nm or more and 200 nm or less.

5. The multilayer wiring film according to claim 3, wherein the wiring layer has a thickness of 50 nm or more and 1000 nm or less, and the Cu—X alloy layer has a thickness of 5 nm or more and 200 nm or less.

6. A thin film transistor element comprising the multilayer wiring film according to claim 1 and an oxide semiconductor.

7. A thin film transistor element comprising the multilayer wiring film according to claim 2 and a low temperature poly-silicon semiconductor or an oxide semiconductor.

8. The multilayer wiring film according to claim 2, wherein the multilayer wiring film is laminated on a substrate, and the multilayer wiring film further comprises an adhesive layer containing Ti on a surface that is closer to the substrate.

9. The multilayer wiring film according to claim 2, wherein the wiring layer has a thickness of 50 nm or more and 1000 nm or less, and the Cu—X alloy layer has a thickness of 5 nm or more and 200 nm or less.
